(19) United States
(12) Patent Application Publication
(10) Pub. No.: US 2026/0165471 A1
(43) Pub. Date: Jun. 18, 2026

(54) SLIDE RAIL ASSEMBLY AND SLIDE RAIL MECHANISM HAVING THE SAME

(71) Applicant: NAN JUEN INTERNATIONAL CO., LTD., Taoyuan City (TW)

(72) Inventors: Fu-Tien CHANG, Taoyuan City (TW); Feng-Ming CHUANG, Taoyuan City (TW); Chih-Yi LIEN, Taoyuan City (TW)

(21) Appl. No.: 19/411,790

(22) Filed: Dec. 8, 2025

(30) Foreign Application Priority Data
Dec. 13, 2024 (TW) 113148928

(51) Int. Cl. A47B 88/473; A47B 88/493; H05K 7/14

(52) U.S. Cl. CPC A47B 88/473; A47B 88/493; A47B 2210/0018; H05K 7/1489

(57) ABSTRACT

A slide rail assembly includes a rail member that has a hold portion, a middle block member that is disposed on the rail member, and an operation member that has a resilient plate and a middle push portion. The resilient plate has a first resilient portion. When the first resilient portion of the resilient plate engages the hold portion of the rail member upon operating the operation member, the operation member is not movable relative to the rail member. When the first resilient portion of the resilient plate engages the hold portion of the rail member, the middle push portion of the operation member pushes against the middle block member such that the operation member prevents the middle block member from moving.

### CROSS-REFERENCE TO RELATED APPLICATION

This application claims priority to Taiwanese Invention Patent Application No. 113148928, filed on Dec. 13, 2024, the entire disclosure of which is incorporated by reference herein.

### FIELD

The disclosure relates to a slide rail assembly, and more particularly to a slide rail assembly and a slide rail mechanism having the same.

### BACKGROUND

With the development of the computer industry and cloud computing, demand for electronic data storage and electronic date access is growing, especially for electronic data related to artificial intelligence (e.g., ChatGPT). In order to meet the demands for massive data storage/access, a modern structure of server equipment consists of a single server rack and a plurality of server chassis disposed in the server rack. The server chassis and the server rack are connected via a slide rail structure. In one example, two opposite sides of each of the server chassis are respectively provided with two first slide rails, and two opposite sides of an interior of the server rack are respectively provided with two second slide rails which correspond in position to the first slide rails disposed on each of the server chassis. The first slide rails that are disposed on each of the server chassis are movable relative to the second slide rails.

### SUMMARY

Therefore, an object of the disclosure is to provide a slide rail assembly that has a configuration different from the abovementioned prior art.

According to the disclosure, the slide rail assembly includes a rail member, a middle block member, and an operation member. The rail member has a hold portion. The middle block member is disposed on the rail member. The operation member has a resilient plate and a middle push portion. The resilient plate has a first resilient portion. When the first resilient portion of the resilient plate engages the hold portion of the rail member upon operating the operation member, the operation member is not movable relative to the rail member. The middle push portion of the operation member pushes against the middle block member when the first resilient portion of the resilient plate engages the hold portion of the rail member such that the operation member prevents the middle block member from moving.

According to another aspect of the disclosure, the slide rail assembly includes a rail member, a block unit, a first rail, a second rail, and an operation member. The rail member has a hold portion. The block unit is disposed on the rail member. The first rail is movably connected to the rail member. The second rail is movably connected to the first rail. The operation member is located between the rail member and the first rail, and has a resilient plate. The resilient plate has a first resilient portion that corresponds in position to the hold portion. The operation member is accessible when the rail member, the first rail and the second rail are extended. When the first resilient portion of the resilient plate engages the hold portion of the rail member upon operating the operation member, the block unit is not blocked by the first rail such that the rail member is operable to move relative to the first rail.

According to still another aspect of the disclosure, the slide rail assembly includes a rail member, a first rail, a second rail, and an operation member. The rail member has a hold portion. The first rail is movably connected to the rail member, and has a block body. The second rail is movably connected to the first rail. The operation member is located between the rail member and the first rail, and has a resilient plate. The resilient plate has a first resilient portion that corresponds in position to the hold portion. The operation member is accessible when the rail member, the first rail and the second rail are extended. When the first resilient portion of the resilient plate engages the hold portion of the rail member upon operating the operation member, the operation member is not movable relative to the rail member. The operation member further has a middle push portion. A block member is disposed on the rail member. When the first resilient portion of the resilient plate engages the hold portion of the rail member, the middle push portion of the operation member pushes against the block member such that the operation member prevents the block member from moving, and that the block member is not blocked by the block body when the rail member is urged to move relative to the first rail.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a fragmentary perspective view illustrating a first embodiment of a slide rail mechanism according to the disclosure.

FIG. 2 is a fragmentary, partly exploded perspective view of the first embodiment.

FIG. 3 is a partly exploded perspective view illustrating a slide rail assembly, a switch structure of a slide rail device, a shift structure of the slide rail device, and an auxiliary structure of the slide rail device of the first embodiment.

FIG. 4 is a schematic front view of the first embodiment illustrating that the slide rail assembly is locked by the switch structure.

FIG. 5 is a schematic front view of part of the first embodiment illustrating that the slide rail assembly is locked by the switch structure.

FIG. 6 is a schematic rear view of part of the first embodiment illustrating that the slide rail assembly is locked by the switch structure.

FIG. 6A is a schematic view illustrating the shift structure holding a support frame of the slide rail device of the first embodiment.

FIG. 6B is a schematic view illustrating a shift structure of a second embodiment of the slide rail mechanism according to the disclosure holding a support frame of a slide rail device of the second embodiment.

FIG. 6C is a schematic view illustrating a shift structure of a third embodiment of the slide rail mechanism according to the disclosure holding a support frame of a slide rail device of the third embodiment.

FIG. 7 is a schematic front view of the first embodiment illustrating that the slide rail assembly is unlocked by the switch structure.

FIG. 8 is a schematic front view of part of the first embodiment illustrating that the slide rail assembly is unlocked by the switch structure.

FIG. 9 is a schematic rear view of part of the first embodiment illustrating that the slide rail assembly is unlocked by the switch structure.

FIG. 10 is a fragmentary perspective view of the first embodiment illustrating that the slide rail assembly is unlocked by the switch structure.

FIG. 11 is another fragmentary perspective view of the first embodiment illustrating that the slide rail assembly is unlocked by the switch structure.

FIG. 12 is a fragmentary, schematic front view of the first embodiment illustrating that the slide rail assembly is urged by the shift structure to move relative to the support frame.

FIG. 13 is a schematic front view of part of the first embodiment illustrating that the slide rail assembly is urged by the shift structure to move relative to the support frame.

FIG. 14 is a schematic rear view of part of the first embodiment illustrating that the slide rail assembly is urged by the shift structure to move relative to the support frame.

FIG. 15 is a schematic front view of part of the first embodiment illustrating that the auxiliary structure is positioned at the support frame.

FIG. 16 is a schematic rear view of part of the first embodiment illustrating that the auxiliary structure is positioned at the support frame.

FIG. 17 is a fragmentary perspective view of the first embodiment illustrating that the slide rail assembly is unlocked by the auxiliary structure.

FIG. 18 is a fragmentary, schematic front view of the first embodiment illustrating that the slide rail assembly is extended.

FIG. 19 is a fragmentary, schematic rear view of the first embodiment illustrating that the slide rail assembly is extended.

FIG. 20 is a fragmentary perspective view of a modification of the first embodiment.

FIG. 21 is another fragmentary perspective view of the modification of the first embodiment.

FIG. 22 is a flow diagram illustrating a method for operating the slide rail mechanism in accordance with some embodiments.

FIG. 23 is a schematic view illustrating a first resilient portion of a resilient plate of the first embodiment engaging a hold portion of a rail member of the slide rail assembly of the first embodiment.

FIG. 24 is another schematic view illustrating the first resilient portion of the resilient plate engaging the hold portion of the rail member.

FIG. 25 is a schematic view illustrating the first resilient portion of the resilient plate being separated from the hold portion of the rail member.

FIG. 26 is another schematic view illustrating the first resilient portion of the resilient plate being separated from the hold portion of the rail member.

FIG. 27 is a schematic view illustrating that two opposite sides of a block body of the first embodiment respectively face a middle block member and a rear block member of the first embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

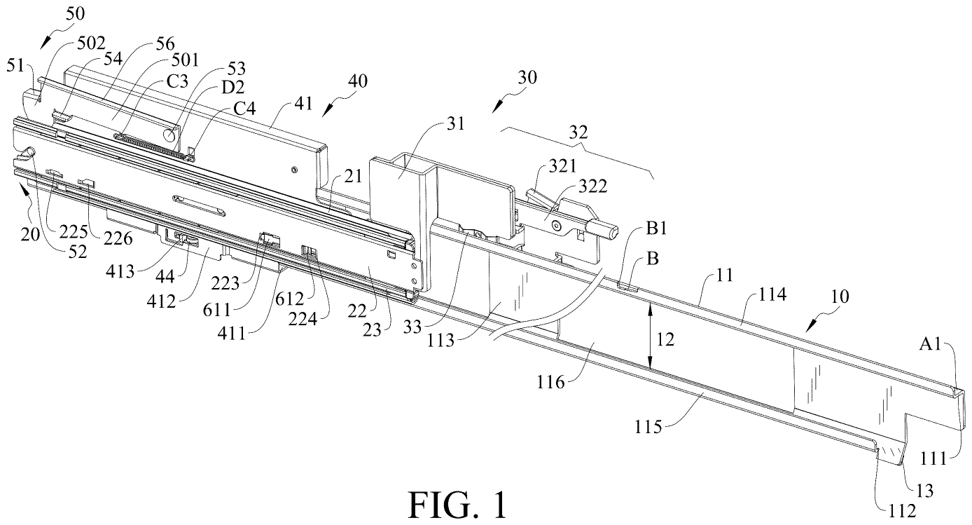

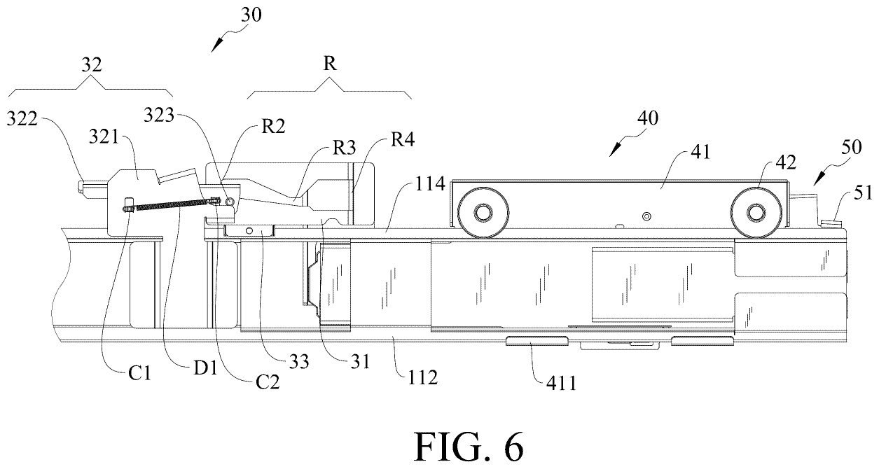

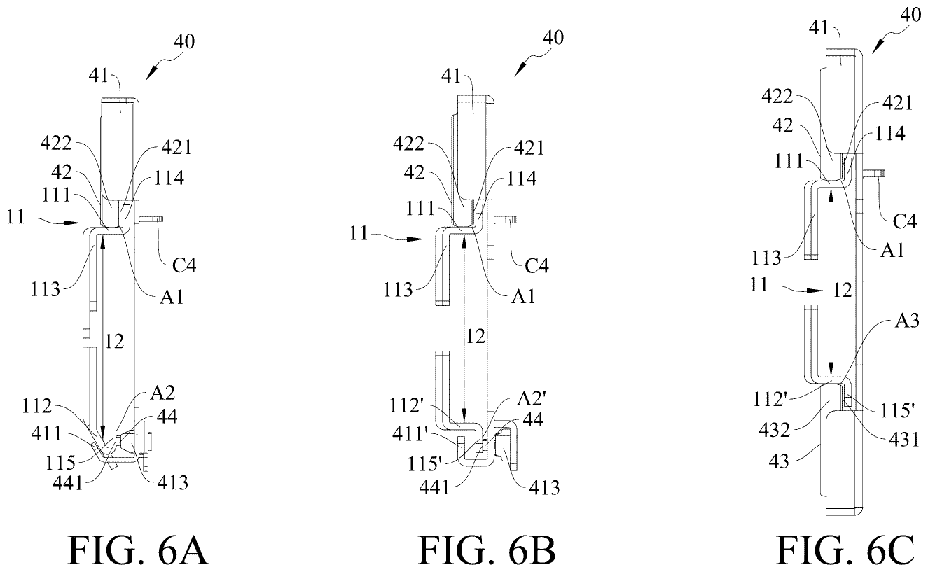

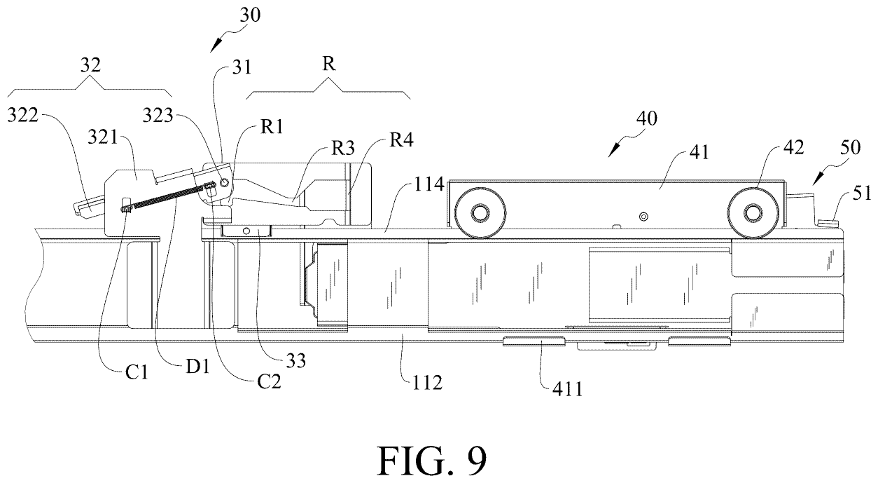

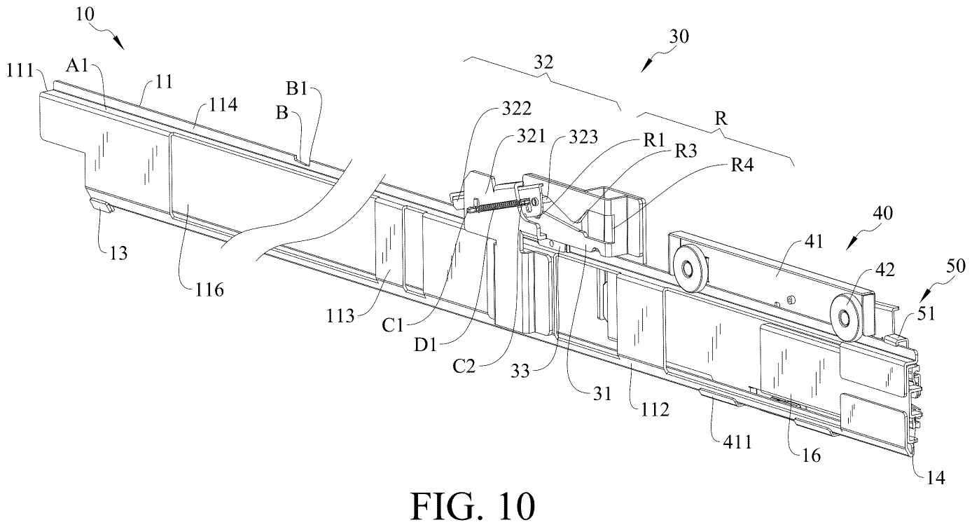

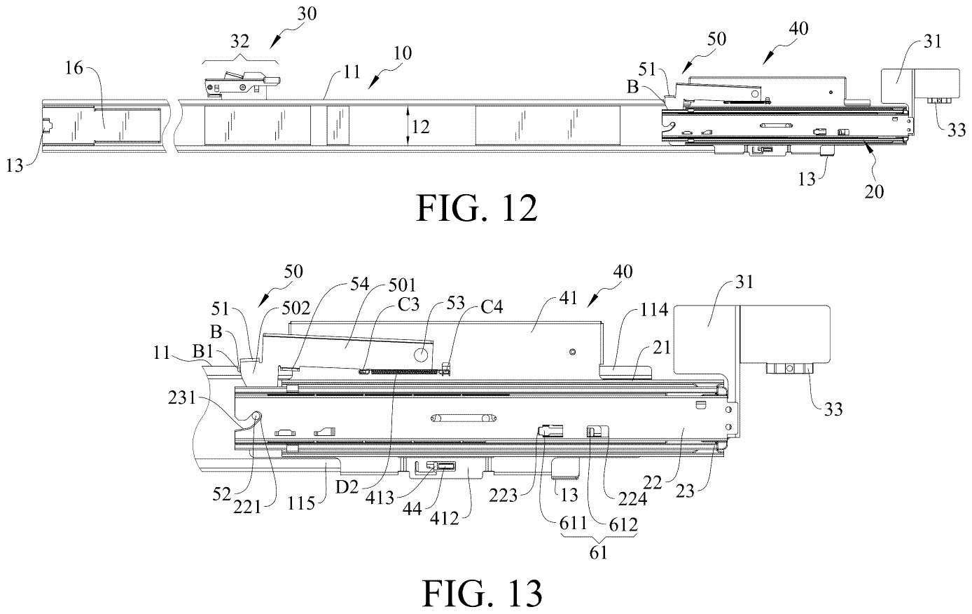

Referring to FIGS. 1 to 6, 7 to 19, and 22 to 27, a first embodiment of a slide rail mechanism according to the disclosure includes a slide rail device 10 and a slide rail assembly 20. The slide rail device 10 includes a support frame 11, a switch structure 30, a shift structure 40, and an auxiliary structure 50. The support frame 11 has a first wall 111, a second wall 112, a third wall 113, a fourth wall 114, and a fifth wall 115. The third wall 113 is substantially vertical, interconnects the first wall 111 and the second wall 112, and cooperates with the first wall 111 and the second wall 112 to form a channel 12. The fourth wall 114 extends upwardly from the first wall 111. The fifth wall 115 extends upwardly from the second wall 112. The second wall 112 is connected to the fifth wall 115, and the second wall 112 and the fifth wall 115 cooperatively have a cross section that is V-shaped (see FIG. 6A). The first wall 111 has a first guiding surface (A1). The fourth wall 114 has a positioning feature (B) that is configured to be a gap. The slide rail assembly 20 is movable relative to the support frame 11 via the first guiding surface (A1). The slide rail assembly 20 is operable to be positioned at the support frame 11 via the positioning feature (B).

The front of the support frame 11 has a first block portion 13 and the rear of the support frame 11 has a second block portion 14 such that the first block portion 13 and the second block portion 14 of the support frame 11 cooperatively limit movement of the slide rail assembly 20 therebetween.

The switch structure 30 includes a route plate 31 and a guide unit 32 that corresponds in position to the route plate 31. One of the route plate 31 and the guide unit 32 is disposed on the slide rail assembly 20, and another one of the route plate 31 and the guide unit 32 is disposed on the support frame 11. When the route plate 31 is disposed on the slide rail assembly 20, the guide unit 32 is disposed on the slide rail device 10 such that the route plate 31 is operable to move and that the guide unit 32 is not moved along the support frame 11 and passively guides the route plate 31. When the route plate 31 is disposed on the slide rail device 10, the guide unit 32 is disposed on the slide rail assembly 20 such that the route plate 31 is not moved along the support frame 11 and that the guide unit 32 is operable to move. When the guide unit 32 is urged to move, the guide unit 32 guides the slide rail assembly 20 such that the slide rail assembly 20 is locked at the support frame 11 or unlocked. Specifically, according to movement of the guide unit 32 relative to the route plate 31, the guide unit 32 locks or unlocks the route plate 31, thereby urging the slide rail assembly 20 to be locked at the support frame 11 or to be unlocked.

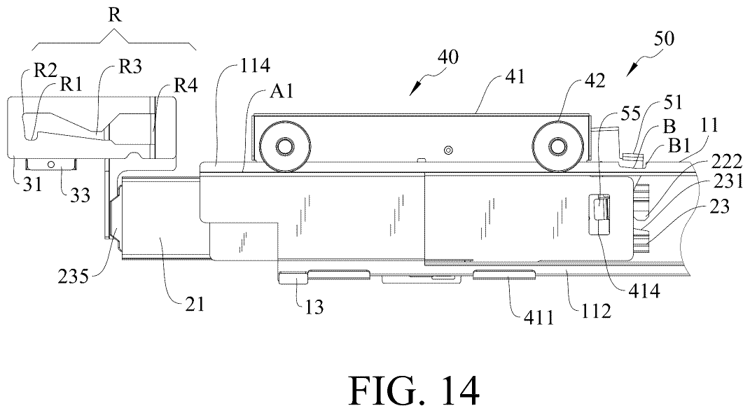

In the first embodiment, the route plate 31 is disposed on the slide rail assembly 20. The route plate 31 has a route (R) (see FIGS. 6 and 14). The route (R) has a lock groove (R1), a limitation arc (R2), a narrow gap (R3), and a stepped opening (R4). The lock groove (R1) extends in an up-down direction. The narrow gap (R3) is located between the limitation arc (R2) and the stepped opening (R4) in a transverse direction transverse to the up-down direction, and tapers toward the stepped opening (R4). The guide unit 32 is disposed on the slide rail device 10. The guide unit 32 includes a frame body 321, a handle 322 that is rotatably connected to the frame body 321, and a guide body 323 that is disposed on the handle 322. The guide body 323 is operable to move along the route (R). During a process of unlocking the route plate 31, the route plate 31 is urged to move relative to the guide body 323 so that the guide body 323 leaves the lock groove (R1) and moves to the limitation arc (R2), the narrow gap (R3), and the stepped opening (R4) sequentially, thereby leaving the route (R). During a process of locking the route plate 31, the route plate 31 is urged to move relative to the guide body 323 so that the guide body 323 enters the stepped opening (R4) and moves to the narrow gap (R3), the limitation arc (R2) and the lock groove (R1) sequentially, thereby staying at the lock groove (R1). In addition, the switch structure 30 may further include a guide feature 33. The guide feature 33 may be formed with a wavy surface. The guide feature 33 corresponds in position to the fourth wall 114, and guides the route plate 31 when the route plate 31 is urged to move relative to the guide unit 32 so that the guide body 323 may smoothly move along the route (R).

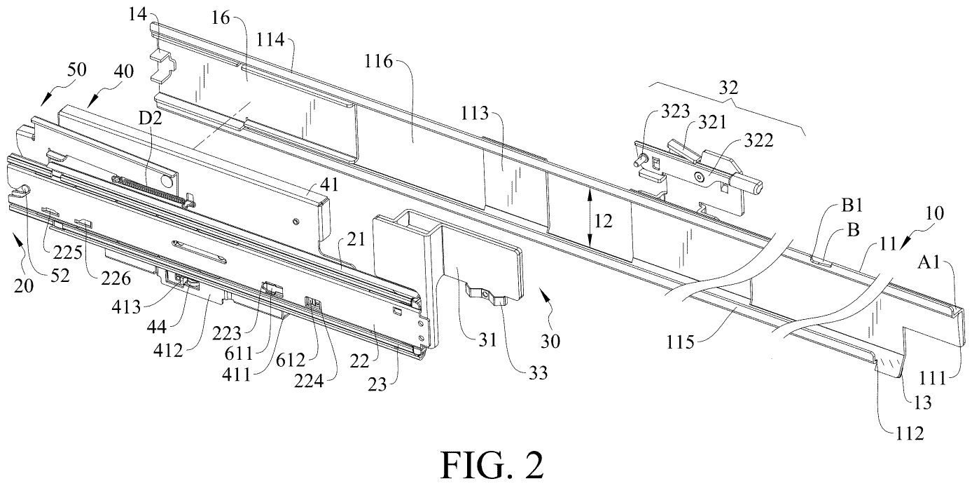

Referring to FIGS. 2 and 6, one end of the frame body 321 distal to a joint between the frame body 321 and the handle 322 has a first fixation portion (C1). One end of the handle 322 proximate to the joint between the frame body 321 and the handle 322 has a second fixation portion (C2). A first resilient member (D1) is provided. One end of the first resilient member (D1) is connected to the first fixation portion (C1). Another end of the first resilient member (D1) is connected to the second fixation portion (C2). By virtue of the first resilient member (D1) providing a restoring force, when the guide body 323 is at the limitation arc (R2) during the process of unlocking the route plate 31, the guide body 323 may smoothly fall toward a bottom of the narrow gap (R3) and move to the stepped opening (R4).

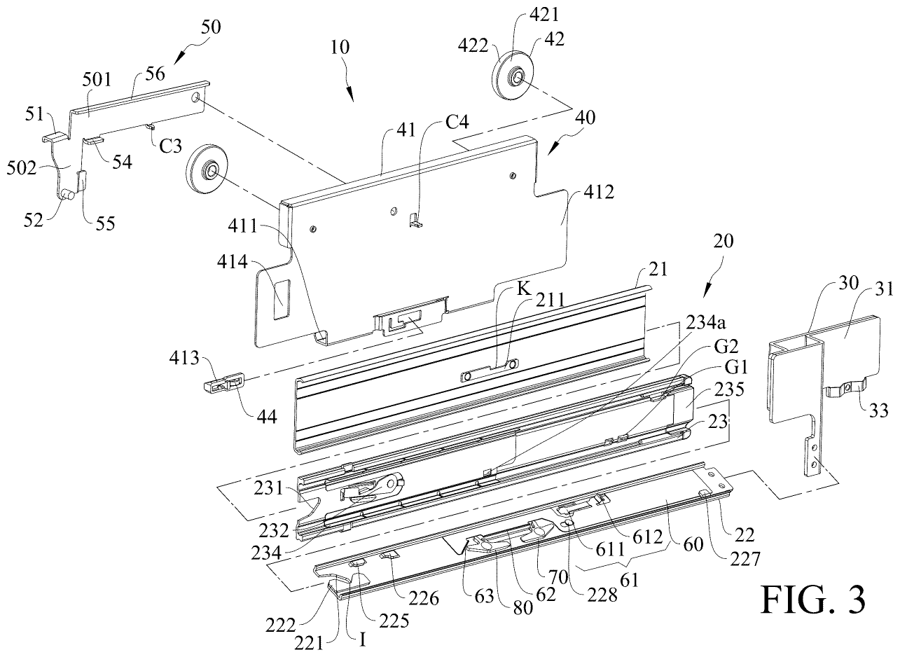

The shift structure 40 includes an installation member 41 and at least one first roller member 42 that is disposed on an upper portion of the installation member 41. The first roller member 42 has a rolling surface 422 (see FIG. 3) that is in contact with the first guiding surface (A1) (see FIG. 6A) and that is operable to roll along the first guiding surface (A1). The first roller member 42 further has a lateral surface 421 that faces the fourth wall 114. Referring to FIG. 6A, the fourth wall 114 is located between the lateral surface 421 of the first roller member 42 and the installation member 41. In the first embodiment, as shown in FIG. 6A, a lower end of the installation member 41 has a holding wall 411 that extends upwardly, that is oblique to the up-down direction, and that holds the second wall 112 of the support frame 11. Referring to FIG. 6B, a second embodiment of the slide rail mechanism according to the disclosure differs from the first embodiment in structural design of the slide rail device 10. In the second embodiment, the second wall 112′ extends horizontally and the fifth wall 115′ extends downwardly from the second wall 112′ such that the second wall 112′ and the fifth wall 115′ cooperatively have a cross section that is L-shaped. Referring to FIG. 6C, a third embodiment of the slide rail mechanism according to the disclosure differs from the first embodiment and the second embodiment in structural design of the slide rail device 10. In the third embodiment, at least one second roller member 43 is disposed on a lower portion of the installation member 41, and the fifth wall 115′ is located between a lateral surface 431 of the second roller member 43 and the installation member 41. The second roller member 43 is in rollable contact with a bottom surface of the second wall 112′ such that the lateral surface 421 of the first roller member 42 and the lateral surface 431 of the second roller member 43 cooperatively hold the fourth wall 114 and the fifth wall 115'. Therefore, the shift structure 40 may smoothly roll along the support frame 11.

Referring to FIGS. 6A and 6B, in each of the first and second embodiments, the fifth wall 115, 115′ has a second guiding surface (A2, A2′) that faces the installation member 41, and a lateral surface 412 of the installation member 41 is provided with at least one third roller member 44 (see FIG. 3). The third roller member 44 has a rolling surface 441 that is rollable on the second guiding surface (A2, A2'). As shown in FIG. 6A, in the first embodiment, the fifth wall 115 extends upwardly toward the channel 12. As shown in FIG. 6B, in the second embodiment, the fifth wall 115′ extends downwardly away from the channel 12, and a lower end of the installation member 41 has a holding wall 411′ such that the fifth wall 115′ is held between the holding wall 411′ and the third roller member 44. As shown in FIG. 6C, the second wall 112′ has a third guiding surface (A3), and the second roller member 43 is rollable on the third guiding surface (A3) via a rolling surface 432 thereof. In the third embodiment, a rotation axis of each of the first roller member 42 and the second roller member 43 extends in a horizontal direction, and the rolling surface 421 of the first roller member 42 and the rolling surface 431 of the second roller member 43 face each other. In the first and second embodiments, a rotation axis of the third roller member 44 extends in the up-down direction such that the rolling surface 441 of the third roller member 44 and the rolling surface 421 of the first roller member 42 do not face each other. In addition, in each of the first and second embodiments, the shift structure 40 may further include a seat body 413 (see FIGS. 3, 6A and 6B) that is removably disposed on the installation member 41, and the third roller member 44 is disposed on the seat body 413.

The auxiliary structure 50 is located between the shift structure 40 and the slide rail assembly 20, and has a first plate body 501, a second plate body 502, a first lock feature 51 and a second lock feature 52. The first plate body 501 extends substantially in the transverse direction. The second plate body 502 extends substantially downwardly from the first plate body 501. The first lock feature 51 and the second lock feature 52 are disposed on the second plate body 502, and the second lock feature 52 is located below the first lock feature 51. The first lock feature 51 is configured to be a protruding plate that is formed by bending part of the second plate body 502. The second lock feature 52 is configured to be a pin body that protrudes from the second plate body 502. The protruding plate and the pin body extend in two opposite directions (i.e., the first lock feature 51 and the second lock feature 52 extend from the second plate body 502 and extend away from each other). The first lock feature 51 is operable to move along the fourth wall 114, and falls into the positioning feature (B) when arriving at the positioning feature (B). The second lock feature 52 is urged to move downwardly at the same time when the first lock feature 51 falls. The first lock feature 51 is operable to be locked at the support frame 11 or be unlocked so that the second lock feature 52 unlocks or locks the slide rail assembly 20.

The slide rail assembly 20 includes a first rail 23, a rail member 22, a block unit 70a, a second rail 21, and an operation member 60. The first rail 23 is located between the second rail 21 and the rail member 22. Therefore, the first rail 23 may be configured to be an intermediate frame, the rail member 22 may be configured to be an inner frame, and the second rail 21 may be configured to be an outer frame. The second rail 21 is fixedly mounted to the installation member 41. The rail member 22 has a first unlock feature 221, and the first rail 23 has a second unlock feature 231. The first unlock feature 221 is configured to be a curved hole, and the second unlock feature 231 has a curved concave edge that corresponds in shape to part of the curved hole (i.e., part of the first unlock feature 221). When the second lock feature 52 unlocks or locks the slide rail assembly 20, the second lock feature 52 of the auxiliary structure 50 specifically unlocks or locks the first unlock feature 221 and the second unlock feature 231. When the first lock feature 51 is moved along the fourth wall 114, the second lock feature 52 locks the first unlock feature 221 and the second unlock feature 231. At this time, the rail member 22 is not movable relative to the first rail 23. When the first lock feature 51 arrives at the positioning feature (B), the first lock feature 51 falls, and the second lock feature 52 falls accordingly such that the second lock feature 52 unlocks the first unlock feature 221 and the second unlock feature 231. At this time, the rail member 22 is movable relative to the first rail 23. The rail member 22 further has a guide plate 222 that has a concave portion (I). The concave portion (I) of the guide plate 222 has a curved edge that corresponds in shape to another part of the first unlock feature 221.

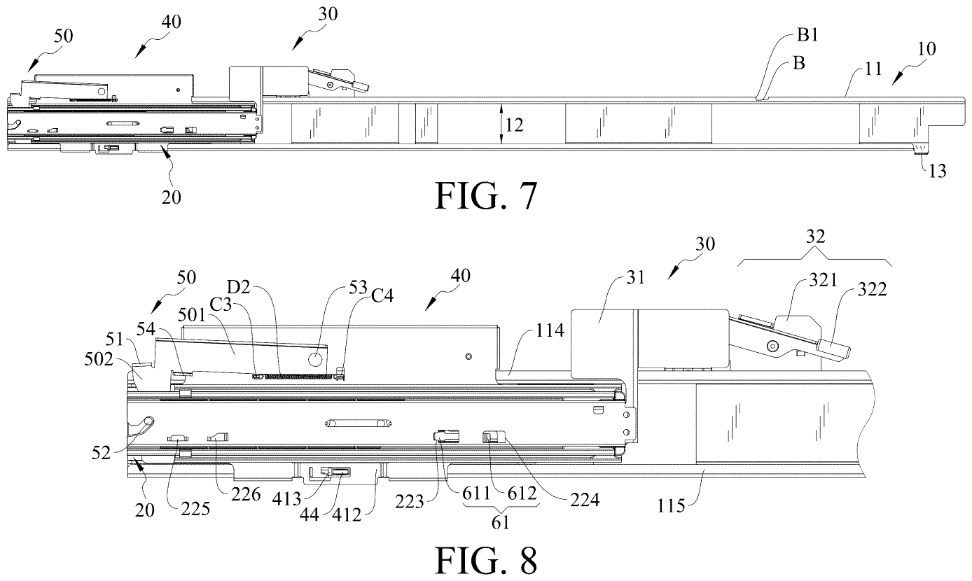

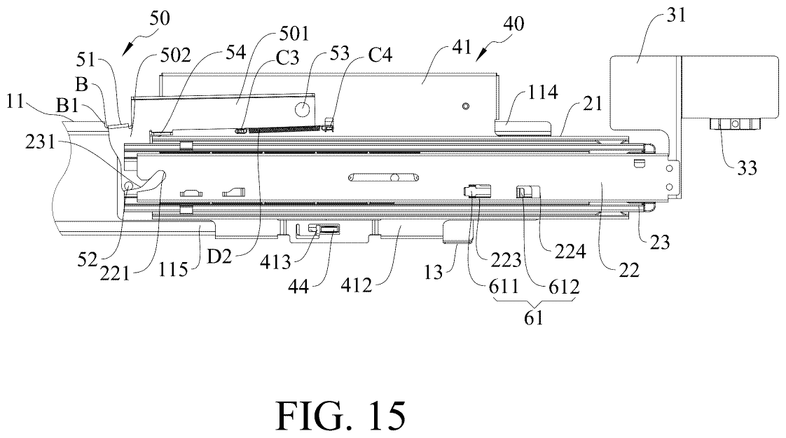

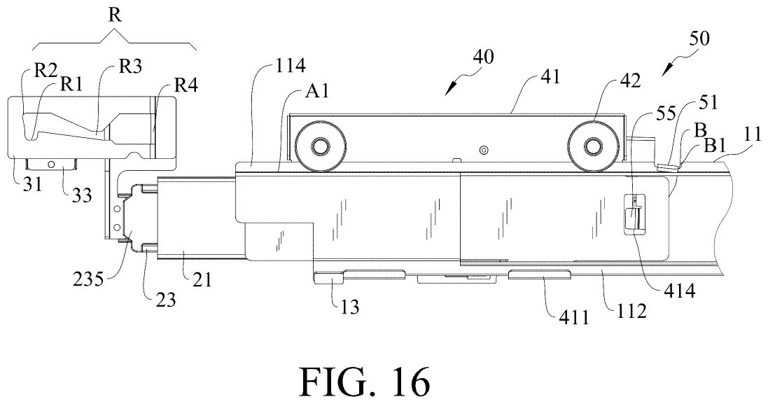

The first plate body 501 is rotatably connected to the installation member 41 such that the auxiliary structure 50 is connected to the shift structure 40. The shift structure 40 and the auxiliary structure 50 are disposed between the support frame 11 and the slide rail assembly 20. A rotation connection member 53 (see FIG. 5) that extends through the first plate body 501 and the installation member 41 is provided so that the first plate body 501 is rotatably connected to the installation member 41. When the first plate body 501 swings, the second plate body 502 swings together. Referring to FIGS. 2 and 3, the first plate body 501 has a third fixation portion (C3), and the installation member 41 of the shift structure 40 has a fourth fixation portion (C4). A second resilient member (D2) is provided. One end of the second resilient member (D2) is connected to the third fixation portion (C3). Another end of the second resilient member (D2) is connected to the fourth fixation portion (C4). By virtue of the second resilient member (D2) providing a restoring force, when the first lock feature 51 arrives at the positioning feature (B), the first lock feature 51 is pulled downwardly such that the auxiliary structure 50 swings downwardly, thereby positioning the second plate body 502 at the positioning feature (B). The positioning feature (B) may have a block surface (B1) (see FIGS. 7 and 15) that prevents the first lock feature 51 from moving rearwardly. A bottom edge of the first plate body 501 has a first limitation plate 54 (see FIG. 3), and an edge of the second plate body 502 that faces the first plate body 501 has a second limitation plate 55 (see FIG. 3). The first limitation plate 54 is operable to limit the movement of the slide rail assembly 20. The installation member 41 further has a limitation opening 414. Referring to FIGS. 14 and 16, the second limitation plate 55 and the limitation opening 414 cooperatively limit a relative position between the auxiliary structure 50 and the shift structure 40. A top edge of the first plate body 501 has a reinforcement rib 56 so that the auxiliary structure 50 may be more convenient for a user to operate (e.g., to press).

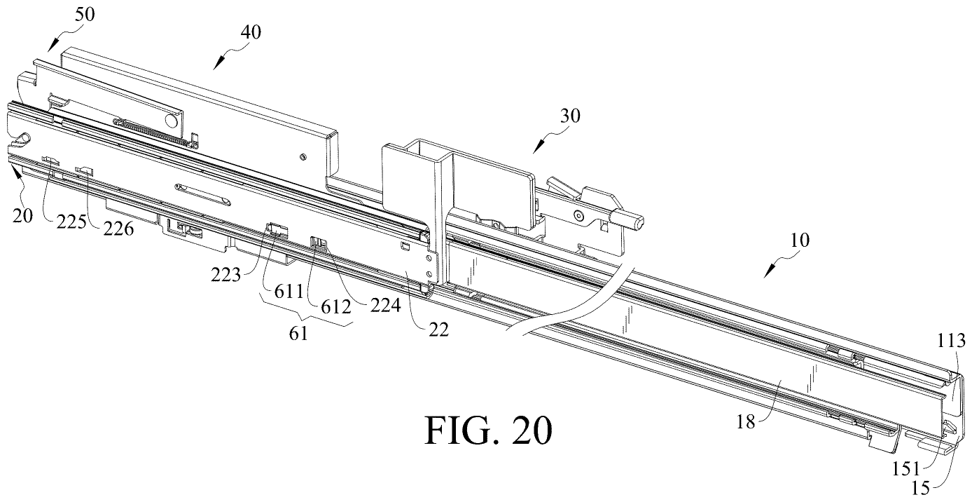

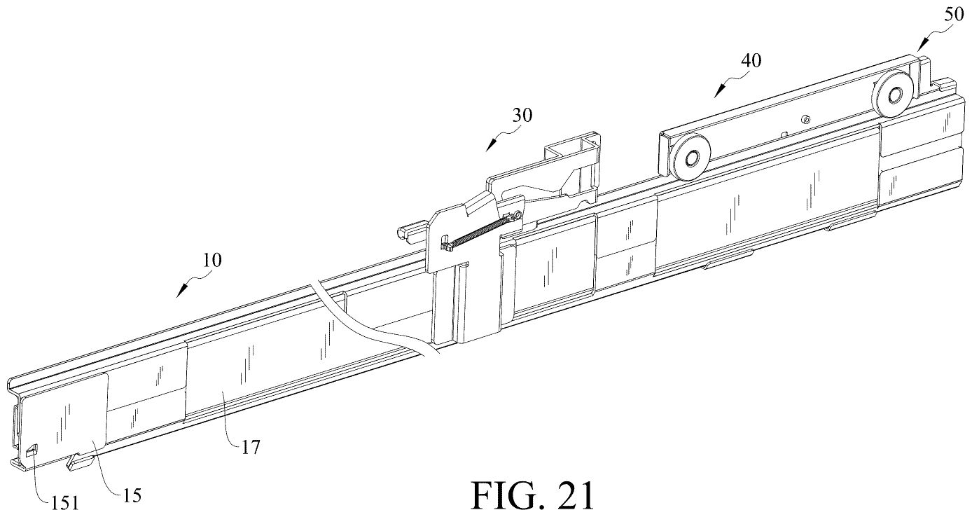

Referring to FIGS. 20 and 21, a modification of the first embodiment includes a first reinforcement frame 15 (not shown in FIG. 1) that has a hook body 151. The first reinforcement frame 15 may be disposed on the third wall 113 of the support frame 11. The support frame 11 further has at least one installation opening 116 (see FIG. 1), and a rear portion thereof includes a second reinforcement frame 16 (see FIG. 2). The second reinforcement frame 16 may be disposed on the installation opening 116. In the modification, the slide rail device 10 further includes a fixation rail 17 (see FIG. 21) and at least one movement rail 18 (see FIG. 20) that is movably connected to the fixation rail 17. The fixation rail 17 may have a protrusion feature that corresponds in position to the installation opening 116 (e.g., the protrusion feature of the fixation rail 17 may extend through the installation opening 116). Components that are disposed on the movement rail 18 may correspond in position to the hook body 151 of the first reinforcement frame 15. The support frame 11 may thus efficiently combine the slide rail assembly 20, the fixation rail 17, and the movement rail 18 together. Consequently, the rail member 22 of the slide rail assembly 20 may be combined with a first load, and the movement rail 18 of the slide rail device 10 may be combined with a second load. In the modification, each of the first load and the second load is configured to be a server chassis.

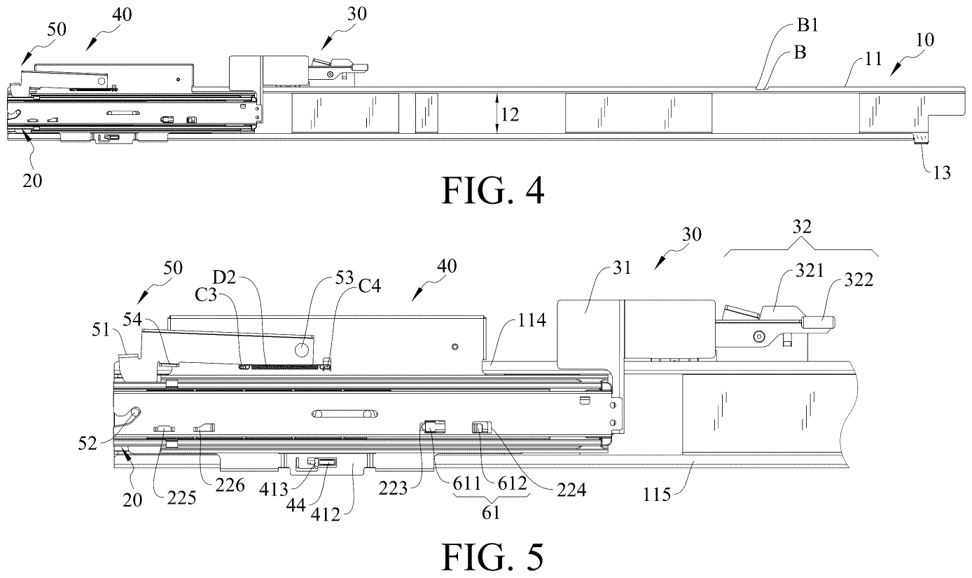

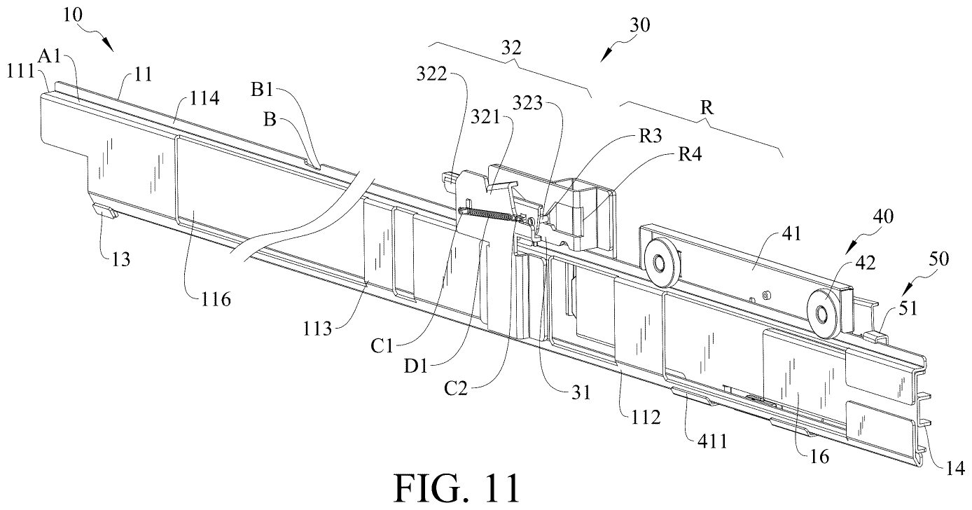

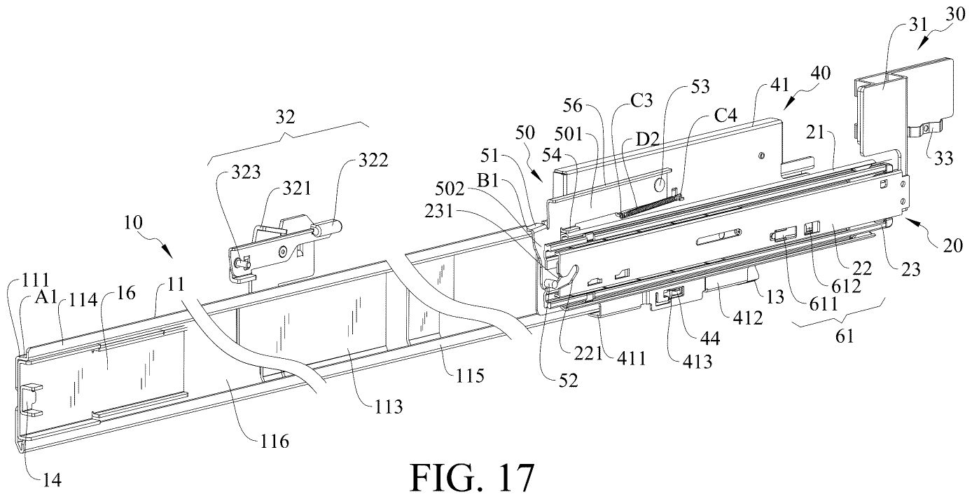

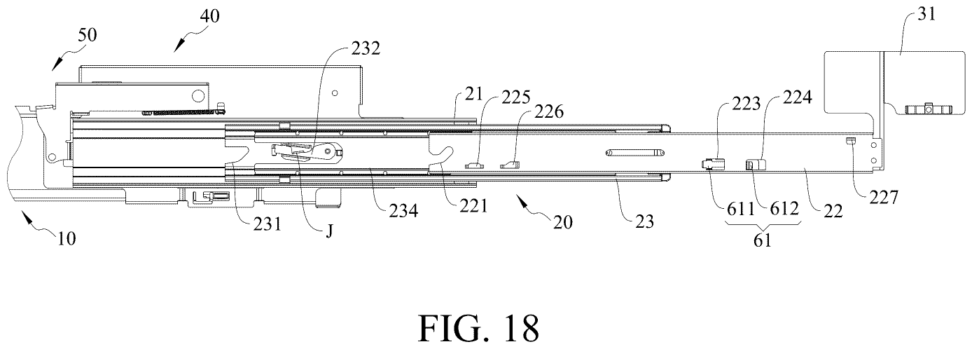

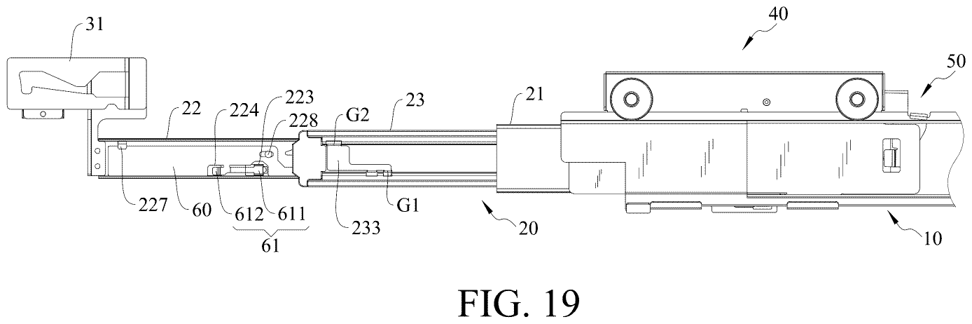

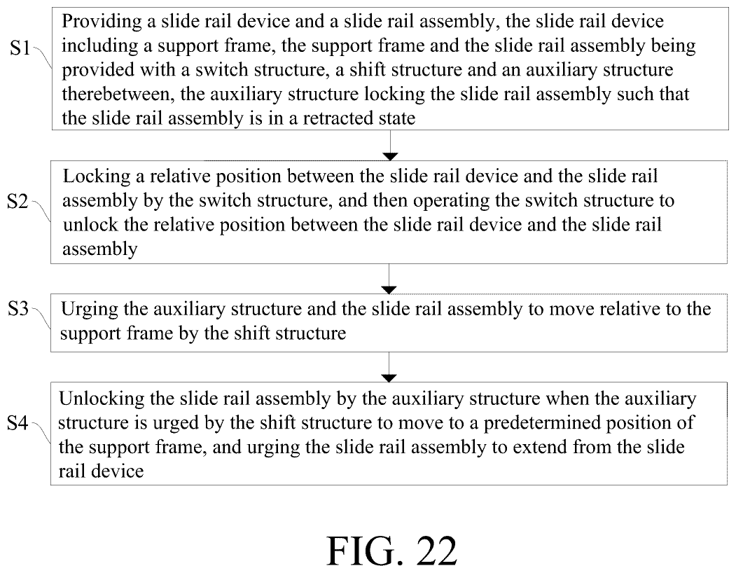

Referring FIG. 22, an embodiment of a method for operating a slide rail mechanism according to the disclosure includes a providing step (S1), a locking/unlocking step (S2), a first moving step (S3), and a second moving step (S4). Referring to FIGS. 1 to 3, during the providing step (S1) of the method, the slide rail device 10 and the slide rail assembly 20 of the first embodiment of the slide rail mechanism is provided. The support frame 11 of the slide rail device 10 and the slide rail assembly 20 are provided with the switch structure 30, the shift structure 40 and the auxiliary structure 50 therebetween. The auxiliary structure 50 locks the slide rail assembly 20 such that the slide rail assembly 20 is in a retracted state. In executing the locking/unlocking step (S2), the switch structure 30 locks a relative position between the slide rail device 10 and the slide rail assembly 20 (see FIGS. 4 to 6), and then the switch structure 30 is operated to unlock the relative position between the slide rail device 10 and the slide rail assembly 20 (see FIGS. 7 to 10). Referring to FIGS. 11 to 14, after the relative position between the slide rail device 10 and the slide rail assembly 20 is unlocked, the first moving step (S3) is executed. In executing the first moving step (S3), the auxiliary structure 50 and the slide rail assembly 20 are urged by the shift structure 40 to move relative to the support frame 11. Afterwards, referring to FIGS. 16 and 17, in executing the second moving step (S4), the auxiliary structure 50 that is urged to move relative to the support frame 11 by the shift structure 40 is moved to a predetermined position (i.e., the first lock feature 51 falls into the positioning feature (B)), and the second lock feature 52 unlocks the slide rail assembly 20. Then, referring to FIGS. 18 and 19, in executing the second moving step (S4), when the slide rail assembly 20 is unlocked and urged to move relative to the slide rail device 10, the slide rail assembly 20 extends from the slide rail device 10 (i.e., the slide rail assembly 20 is in an extended state). It is noted that, when the steps of the method for operating the slide rail mechanism are executed reversely, the slide rail assembly 20 is converted from the extended state to the retracted state, and is locked by the auxiliary structure 50. Therefore, for the sake of brevity, there will be no detailed description of converting the slide rail assembly 20 from the extended state to the retracted state.

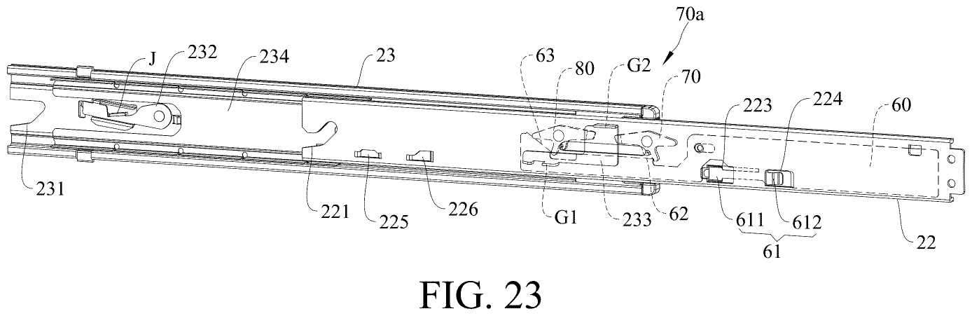

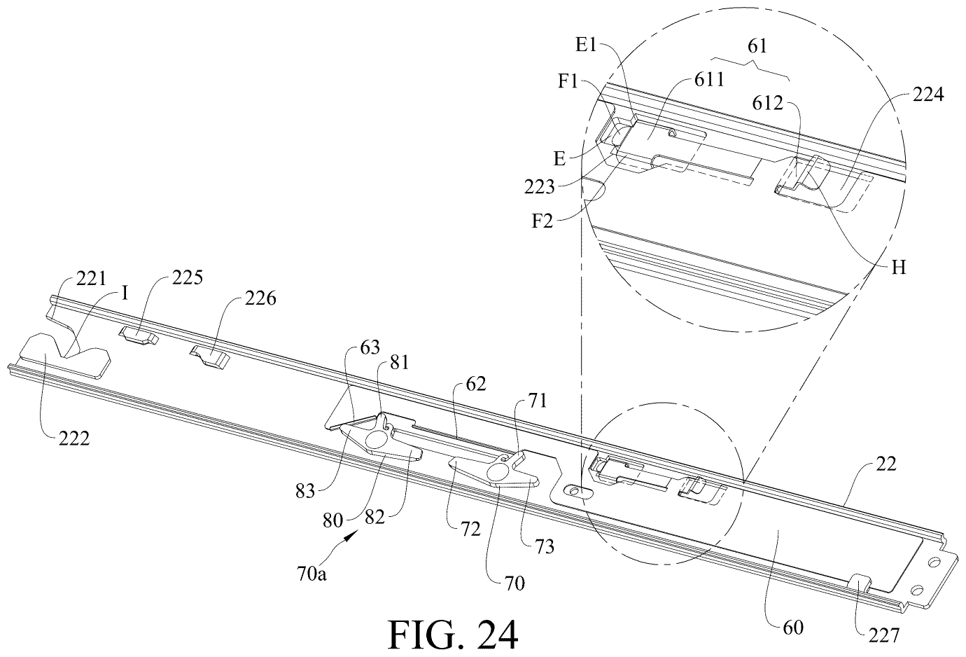

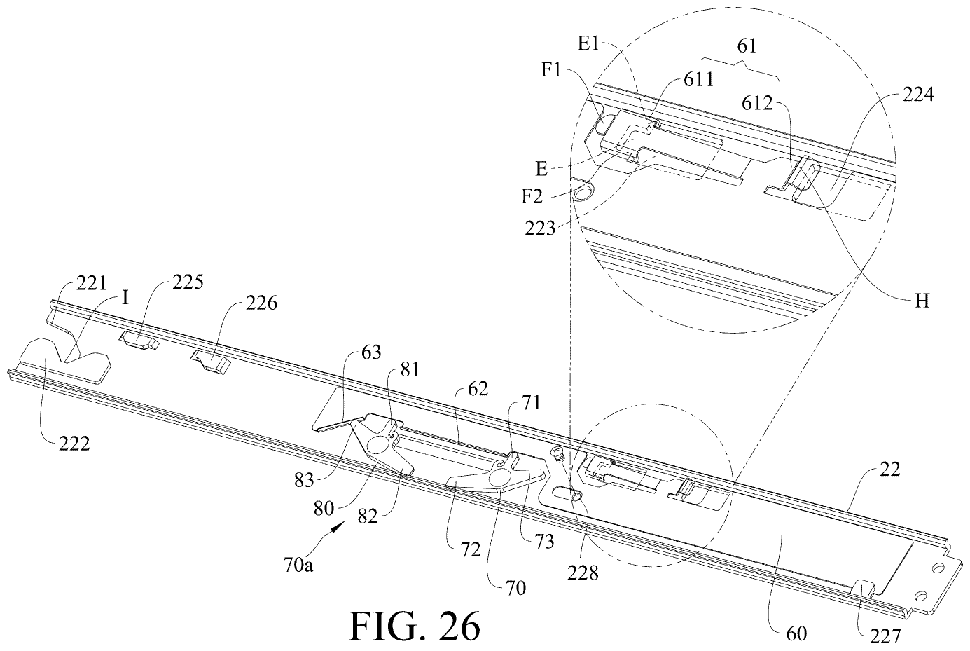

Referring to FIGS. 23 to 27, the rail member 22 has a hold portion 223. In the first embodiment, the hold portion 223 of the rail member 22 is configured to be a through hole that extends through the rail member 22. The operation member 60 has a resilient plate 61 and a main body. The resilient plate 61 has a first resilient portion 611 and a second resilient portion 612 that are located at two opposite ends thereof (i.e., the second resilient portion 612 is opposite to the first resilient portion 611), and a connection portion that is located between the first resilient portion 611 and the second resilient portion 612, and that is connected to the main body of the operation member 60. The operation member 60 is operable to move in a longitudinal direction of the rail member 22. The resilient plate 61 of the operation member 60 extends in a longitudinal direction of the operation member 60. The first resilient portion 611 of the resilient plate 61 corresponds in position to the hold portion 223 of the rail member 22. When the first resilient portion 611 of the resilient plate 61 engages the hold portion 223 of the rail member 22 (i.e., the first resilient portion 611 of the resilient plate 61 enters the hold portion 223 of the rail member 22 for engagement) upon operating the operation member 60, the operation member 60 is not movable relative to the rail member 22. In the first embodiment, the operation member 60 is located between the rail member 22 and the first rail 23, and may be disposed on one of the rail member 22 and the first rail 23. The hold portion 223 of the rail member 22 has an engagement hole (E) that is substantially in a shape of a two-tier cake and that has an abutment surface (E1) which serves as a shoulder section of the hold portion 223. The first resilient portion 611 of the resilient plate 61 has a head section (F1) and a wing section (F2) that is connected to the head section (F1). A width of the wing section (F2) is greater than a width of the head section (F1). The wing section (F2) of the first resilient portion 611 of the resilient plate 61 is operable to abut against the abutment surface (E1) (i.e., to abut against the shoulder section of the hold portion 223 of the rail member 22). As shown in FIG. 24, when the wing section (F2) abuts against the abutment surface (E1), the resilient plate 61 is in an on state. In one embodiment (not shown), the head section (F1) of the first resilient portion 611 of the resilient plate 61 may have a protrusion, and may be operable to abut against a predetermined position of the engagement hole (E) via the protrusion thereof. When the protrusion of the head section (F1) abuts against the predetermined position of the engagement hole (E), the resilient plate 61 is in the on state. The rail member 22 further has a first guide portion 227 and a second guide portion 228. The first guide portion 227 may be hook-shaped, and the second guide portion 228 may be configured as a rivet that extends through an elongated groove of the operation member 60 (see FIG. 26). The first guide portion 227 and the second guide portion 228 limit movement of the operation member 60 so that the operation member 60 is disposed on the rail member 22 and is movable relative to the rail member 22.

The block unit 70a includes a middle block member 70 and a rear block member 80 that are rotatably disposed on the rail member 22. The middle block member 70 and the rear block member 80 are connected by a tension spring. The operation member 60 further has a middle push portion 62 and a rear push portion 63. Upon operating the operation member 60 (e.g., pulling or pushing the operation member 60 in a front-rear direction), the resilient plate 61, the middle push portion 62 and the rear push portion 63 are moved together. In the first embodiment, the middle push portion 62 is configured to be a protruding edge that is located between the middle block member 70 and the rear block member 80. The rear push portion 63 is configured to be a sloping edge that is oblique to the front-rear direction, and is adjacent to the rear block member 80. The rear push portion 63 is adjacent to a rear end of the operation member 60 that is opposite to a front end of the operation member 60. The middle push portion 62 and the resilient plate 61 are located between the rear push portion 63 and the front end of the operation member 60. The resilient plate 61 is closer than the middle push portion 62 is to the front end of the operation member 60, and the middle push portion 62 is closer than the rear push portion 63 is to the front end of the operation member 60. When the first resilient portion 611 of the resilient plate 61 engages the hold portion 223 of the rail member 22, the middle push portion 62 of the operation member 60 pushes against the middle block member 70 and the rear push portion 63 of the operation member 60 pushes against the rear block member 80 such that the operation member 60 prevents the middle block member 70 and the rear block member 80 from moving.

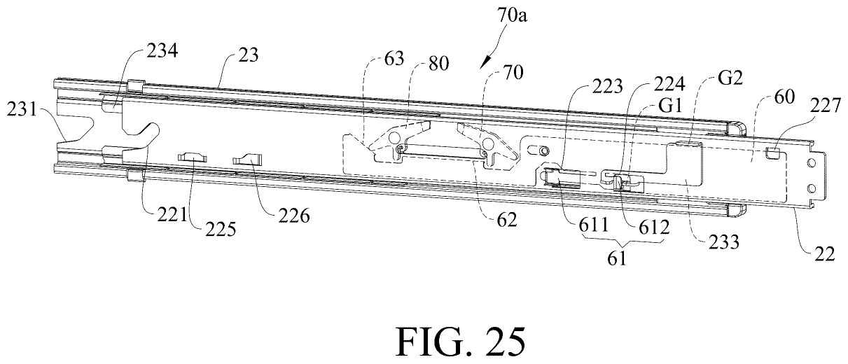

The first resilient portion 611 of the resilient plate 61 is separated from the hold portion 223 of the rail member 22 upon operating the second resilient portion 612 of the resilient plate 61 such that the operation member 60 is movable relative to the rail member 22. The rail member 22 further has an opening 224 that corresponds in position to the second resilient portion 612 of the resilient plate 61. The second resilient portion 612 of the resilient plate 61 is operable in the opening 224. In the first embodiment, when the second resilient portion 612 of the resilient plate 61 is operated (i.e., when the second resilient portion 612 of the resilient plate 61 is pushed toward the opening 224), the wing section (F2) of the first resilient portion 611 of the resilient plate 61 is separated from the abutment surface (E1). As shown in FIG. 26, when the wing section (F2) is separated from the abutment surface (E1), the resilient plate 61 is in an off state. In one embodiment (now shown), the protrusion of the head section (F1) of the resilient plate 61 is separated from the predetermined position of the engagement hole (E) when the second resilient portion 612 of the resilient plate 61 is operated, and the resilient plate 61 is in the off state. Consequently, as shown in FIGS. 25 to 27, the middle block member 70 is not pushed against by the middle push portion 62 of the operation member 60, and the rear block member 80 is not pushed by the rear push portion 63 of the operation member 60. At this time, the middle block member 70 and the rear block member 80 are in an initial state.

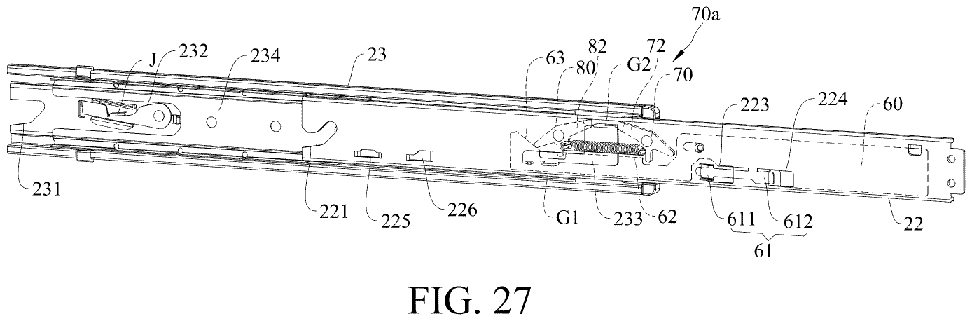

Referring to FIGS. 23 to 27, the first rail 23 is movably connected to the rail member 22, and includes a conversion member 233. The conversion member 233 has a first block body (G1) and a second block body (G2) that protrude toward the rail member 22. The first block body (G1) is operable to engage a seat hole 234a of a roller seat 234 (see FIG. 3). The roller seat 234 is located between the first rail 23 and the rail member 22. The first block body (G1) corresponds in position to the second resilient portion 612 of the resilient plate 61. The second resilient portion 612 of the resilient plate 61 is bent to form a conversion surface (H) that is convex toward the first rail 23 so that when the rail member 22 retracts into the first rail 23, the first block body (G1) urges the second resilient portion 612 of the resilient plate 61. It is noted that in the first embodiment, when the first block body (G1) urges the second resilient portion 612 of the resilient plate 61, the second resilient portion 612 of the resilient plate 61 is resiliently deformed. When the second resilient portion 612 of the resilient plate 61 is urged by the first block body (G1), the first resilient portion 611 of the resilient plate 61 is separated from the hold portion 223 of the rail member 22. Specifically, in the first embodiment, when the rail member 22 retracts into the first rail 23, the conversion surface (H) is pushed against by the first block body (G1) such that the second resilient portion 612 of the resilient plate 61 is pushed toward the opening 224 and resiliently deforms, thereby separating the wing section (F2) of the first resilient portion 611 of the resilient plate 61 from the abutment surface (E1). Consequently, the middle block member 70 and the rear block member 80 are converted to the initial state. The first rail 23 may have only one of the first block body (G1) and the second block body (G2). The second block body (G2) is operable to be moved to a position between the middle block member 70 and the rear block member 80. When the first resilient portion 611 of the resilient plate 61 engages the hold portion 223 of the rail member 22 (i.e., the first resilient portion 611 of the resilient plate 61 enters the hold portion 223 of the rail member 22 for engagement) upon operating the operation member 60, the block unit 70a is not blocked by the first rail 23 such that the rail member 22 is operable to move relative to the first rail 23. Specifically, as shown in FIG. 23, when the middle block member 70 and the rear block member 80 are pushed against by the operation member 60 (i.e., when the first resilient portion 611 of the resilient plate 61 engages the hold portion 223 of the rail member 22), the tension spring that interconnects the middle block member 70 and the rear block member 80 is extended, and the middle block member 70 and the rear block member 80 are not blocked by the second block body (G2) that is located therebetween when the rail member 22 is urged to move relative to the first rail 23. Therefore, the rail member 22 is operable to move relative to the first rail 23 such that the rail member 22 is extended or retracts into the first rail 23, and the rail member 22 is operable to be pulled out from (i.e., removed from) the first rail 23. When the first resilient portion 611 of the resilient plate 61 is separated from the hold portion 223 of the rail member 22 upon operating the second resilient portion 612 of the resilient plate 61, the block unit 70a is blocked by the first rail 23 such that the rail member 22 is prevented from moving relative to the first rail 23. Specifically, as shown in FIG. 27, when the middle block member 70 and the rear block member 80 are in the initial state (i.e., when the first resilient portion 611 of the resilient plate 61 is separated from the hold portion 223 of the rail member 22) and when the second block body (G2) is located between the middle block member 70 and the rear block member 80, the tension spring that interconnects the middle block member 70 and the rear block member 80 is restored, and the rail member 22 is prevented from moving relative to the first rail 23. Therefore, the rail member 22 may not be pulled out from the first rail 23. The first rail 23 further includes a support member 235 (see FIG. 3). When the rail member 22 retracts into the first rail 23, the rail member 22 is supported by the support member 235. When the rail member 22 retracts into the first rail 23, the first guide portion 227 of the rail member 22 pushes the second block body (G2) so that the first rail 23 is urged by the rail member 22 to retract into the second rail 21.

The middle block member 70 has a head end 72, a tail end 73 that is opposite to the head end 72, and an extension end 71 that extends downwardly. The rear block member 80 has a head end 82, a tail end 83 that is opposite to the head end 82, and an extension end 81 that extends downwardly. When the middle block member 70 and the rear block member 80 are in the initial state (i.e., when the tension spring is not extended), the head end 72 of the middle block member 70 and the head end 82 of the rear block member 80 point at a top edge of the rail member 22. Referring to FIG. 24, when the middle push portion 62 of the operation member 60 pushes against the extension end 71 of the middle block member 70, the head end 72 of the middle block member 70 swings downwardly and the tail end 73 of the middle block member 70 swings upwardly. At the same time, referring to FIG. 24, the rear push portion 63 of the operation member 60 pushes against the tail end 83 of the rear block member 80 such that the tail end 83 of the rear block member 80 swings upwardly and that the head end 82 of the rear block member 80 swings downwardly. As shown in FIGS. 23 and 24, when the operation member 60 pushes against the middle block member 70 and the rear block member 80, the head end 72 and the tail end 73 of the middle block member 70 and the head end 82 and the tail end 83 of the rear block member 80 are substantially at a same height (i.e., located on an imaginary horizontal plane). Referring to FIG. 26, during a process of converting the resilient plate 61 from the on state to the off state, the rear push portion 63 of the operation member 60 guides the tail end 83 of the rear block member 80 such that the tail end 83 of the rear block member 80 slides along the rear push portion 63 of the operation member 60 to swing downwardly.

The second rail 21 is movably connected to the first rail 23, and has a fixation member 211 (see FIG. 3). The first rail 23 further has a lock member 232 that corresponds in position to the fixation member 211. When the first rail 23 and the second rail 21 are extended, the lock member 232 is positioned at the fixation member 211 such that the first rail 23 is prevented from moving. In the first embodiment, the lock member 232 has an engagement body (J) (see FIG. 27) that protrudes toward the second rail 21, and the fixation member 211 of the second rail 21 has a recessed body (K) (see FIG. 3). The engagement body (J) is operable to engage the recessed body (K). When the engagement body (J) engages the recessed body (K), the first rail 23 is prevented from moving relative to the second rail 21. The rail member 22 further has a first unlock section 226 that corresponds in position to the lock member 232. When the rail member 22 retracts into the first rail 23, the lock member 232 is separated from the fixation member 211 (i.e., the engagement body (J) is disengaged from the recessed body (K)) by the first unlock section 226 of the rail member 22 such that the first rail 23 is allowed to move.

When the rail member 22 is extended or retracts into the first rail 23, the rail member 22 is in contact with the roller seat 234. The roller seat 234 is in slidable contact with the first rail 23 so that the rail member 22 may smoothly slide relative to the first rail 23 to extend or retract. It is noted that the operation member 60 is accessible when the rail member 22, the first rail 23 and the second rail 21 are extended. When the rail member 22 is extended and arrives at a predetermined position of the first rail 23, the first block body (G1) engages the seat hole 234a of the roller seat 234 such that the roller seat 234 is positioned at the first rail 23. The rail member 22 further has a second unlock section 225 that corresponds in position to the first block body (G1). When the rail member 22 retracts into the first rail 23 and arrives at another predetermined position of the first rail 23, the second unlock section 225 of the rail member 22 pushes against the first block body (G1) to urge the first block body (G1) to be separated from the seat hole 234a, thereby allowing the roller seat 234 to move relative to the first rail 23. That is to say, the second unlock section 225 of the rail member 22 is operable to disengage the engagement between the first block body (G1) and the roller seat 234.

When the first load is combined with a plurality of the slide rail assemblies 20, if the operation member 60 of each of the slide rail assemblies 20 is not provided with the resilient plate 61, a single user may not be able to operate the operation members 60 of the slide rail assemblies 20 to urge the operation member 60 of each of the slide rail assemblies 20 to push against the middle block member 70 and the rear block member 80 of the slide rail assembly 20. The middle block member 70 or the rear block member 80 of at least one of the slide rail assemblies 20 may still be blocked by the second block body (G2) of the at least one of the slide rail assemblies 20. Therefore, the single user may not be able to unload the first load because the rail member 22 of the at least one of the slide rail assemblies 20 is not separable from the first rail 23 of the at least one of the slide rail assemblies 20, or may not be able to push the first load because the rail member 22 of the at least one of the slide rail assemblies 20 fails to retract into the first rail 23 of the at least one of the slide rail assemblies 20. However, by virtue of the resilient plate 61 of the operation member 60 and the hold portion 223 of the rail member 22, the operation member 60 and the rail member 22 of each of the slide rail assemblies 20 may easily engage each other or be disengaged from each other, and the middle block member 70 and the rear block member 80 of the slide rail assembly 20 are efficiently pushed against by the operation member 60. Therefore, the single user may easily operate the operation members 60 of the slide rail assemblies 20 to urge the operation member 60 of each of the slide rail assemblies 20 to push against the middle block member 70 and the rear block member 80 of the slide rail assembly 20, which makes unloading or pushing the first load relatively easy.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A slide rail assembly comprising:
a rail member having a hold portion;
a middle block member disposed on the rail member; and
an operation member having a resilient plate and a middle push portion, the resilient plate having a first resilient portion;
wherein, when the first resilient portion of the resilient plate engages the hold portion of the rail member upon operating the operation member, the operation member is not movable relative to the rail member; and
wherein the middle push portion of the operation member pushes against the middle block member when the first resilient portion of the resilient plate engages the hold portion of the rail member such that the operation member prevents the middle block member from moving.

2. The slide rail assembly as claimed in claim 1, wherein the operation member further has a rear push portion, a rear block member being disposed on the rail member, the rear push portion of the operation member pushing against the rear block member when the first resilient portion of the resilient plate engages the hold portion of the rail member such that the operation member prevents the rear block member from moving.

3. The slide rail assembly as claimed in claim 1, wherein the resilient plate further has a second resilient portion opposite to the first resilient portion, the first resilient portion of the resilient plate being separated from the hold portion of the rail member upon operating the second resilient portion of the resilient plate such that the operation member is movable relative to the rail member.

4. The slide rail assembly as claimed in claim 3, wherein the rail member further has an opening that corresponds in position to the second resilient portion of the resilient plate, the second resilient portion of the resilient plate being operable in the opening.

5. The slide rail assembly as claimed in claim 3, further comprising a first rail that is movably connected to the rail member, the first rail having a first block body that corresponds in position to the second resilient portion of the resilient plate, the first block body urging the second resilient portion of the resilient plate when the rail member retracts into the first rail.

6. The slide rail assembly as claimed in claim 5, wherein:
the slide rail assembly further comprises a rear block member that is disposed on the rail member, the first rail further having a second block body;
when the second resilient portion of the resilient plate is urged by the first block body, the first resilient portion of the resilient plate is separated from the hold portion of the rail member; and
when the second block body is located between the middle block member and the rear block member and when the first resilient portion of the resilient plate is separated from the hold portion of the rail member, the rail member is prevented from moving relative to the first rail.

7. The slide rail assembly as claimed in claim 1, wherein the hold portion of the rail member has an engagement hole that is substantially in a shape of a two-tier cake and that has an abutment surface, the first resilient portion of the resilient plate having a head section and a wing section that is connected to the head section, the wing section of the first resilient portion of the resilient plate being operable to abut against the abutment surface.

8. A slide rail assembly comprising:
a rail member having a hold portion;
a block unit disposed on the rail member;
a first rail movably connected to the rail member;
a second rail movably connected to the first rail; and
an operation member located between the rail member and the first rail, and having a resilient plate, the resilient plate having a first resilient portion that corresponds in position to the hold portion;
wherein the operation member is accessible when the rail member, the first rail and the second rail are extended; and
wherein, when the first resilient portion of the resilient plate engages the hold portion of the rail member upon operating the operation member, the block unit is not blocked by the first rail such that the rail member is operable to move relative to the first rail.

9. The slide rail assembly as claimed in claim 8, wherein the second rail has a fixation member, the first rail having a lock member that corresponds in position to the fixation member, the lock member being positioned at the fixation member when the first rail and the second rail are extended such that the first rail is prevented from moving.

10. The slide rail assembly as claimed in claim 9, wherein the rail member has a first unlock section that corresponds in position to the lock member, the lock member being separated from the fixation member by the first unlock section of the rail member when the rail member retracts into the first rail such that the first rail is allowed to move.

11. The slide rail assembly as claimed in claim 8, wherein the operation member further has a middle push portion, the block unit including a middle block member that is disposed on the rail member, the middle push portion of the operation member pushing against the middle block member when the first resilient portion of the resilient plate engages the hold portion of the rail member such that the operation member prevents the middle block member from moving.

12. The slide rail assembly as claimed in claim 8, wherein the operation member has a rear push portion, the block unit including a rear block member that is disposed on the rail member, the rear push portion of the operation member pushing against the rear block member when the first resilient portion of the resilient plate engages the hold portion of the rail member such that the operation member prevents the rear block member from moving.

13. The slide rail assembly as claimed in claim 8, wherein the resilient plate further has a second resilient portion opposite to the first resilient portion, the first resilient portion of the resilient plate being separated from the hold portion of the rail member upon operating the second resilient portion of the resilient plate such that the operation member is movable relative to the rail member.

14. The slide rail assembly as claimed in claim 13, wherein, when the first resilient portion of the resilient plate is separated from the hold portion of the rail member upon operating the second resilient portion of the resilient plate, the block unit is blocked by the first rail such that the rail member is prevented from moving relative to the first rail.

15. The slide rail assembly as claimed in claim 13, wherein the rail member further has an opening that corresponds in position to the second resilient portion of the resilient plate, the second resilient portion of the resilient plate being operable in the opening.

16. The slide rail assembly as claimed in claim 13, wherein the first rail has a first block body that corresponds in position to the second resilient portion of the resilient plate, the first block body urging the second resilient portion of the resilient plate when the rail member retracts into the first rail.

17. The slide rail assembly as claimed in claim 16, wherein:
the block unit includes a middle block member and a rear block member that are disposed on the rail member, the first rail further having a second block body;
when the second resilient portion of the resilient plate is urged by the first block body, the first resilient portion of the resilient plate is separated from the hold portion of the rail member; and
when the second block body is located between the middle block member and the rear block member and when the first resilient portion of the resilient plate is separated from the hold portion of the rail member, the rail member is prevented from moving relative to any one of the first rail and the second rail.

18. The slide rail assembly as claimed in claim 8, wherein the hold portion of the rail member has an engagement hole that is substantially in a shape of a two-tier cake and that has an abutment surface, the first resilient portion of the resilient plate having a head section and a wing section that is connected to the head section, the wing section of the first resilient portion of the resilient plate being operable to abut against the abutment surface.

19. A slide rail assembly comprising:
a rail member having a hold portion;
a first rail movably connected to the rail member and having a block body;
a second rail movably connected to the first rail; and
an operation member located between the rail member and the first rail, and having a resilient plate, the resilient plate having a first resilient portion that corresponds in position to the hold portion;
wherein, the operation member is accessible when the rail member, the first rail and the second rail are extended;
wherein, when the first resilient portion of the resilient plate engages the hold portion of the rail member upon operating the operation member, the operation member is not movable relative to the rail member;
wherein the operation member further has a middle push portion, a block member being disposed on the rail member; and
wherein, when the first resilient portion of the resilient plate engages the hold portion of the rail member, the middle push portion of the operation member pushes against the block member such that the operation member prevents the block member from moving, and that the block member is not blocked by the block body when the rail member is urged to move relative to the first rail.

20. The slide rail assembly as claimed in claim 19, wherein the resilient plate of the operation member extends in a longitudinal direction of the operation member.
